(19) United States
(12) Patent Application Publication
(10) Pub. No.: US 2026/0313861 A1
(43) Pub. Date: Oct. 8, 2026

(54) Thermal Regulation of High Power Spacecraft Electronics via Encapsulation in Phase Change Material

(71) Applicant: Starcloud, Inc., REDMOND, WA (US)

(72) Inventors: Paul Adrian Oltean, Bellevue, WA (US); Ezra Feilden, Reading (GB); Philip Johnston, Los Angeles, CA (US)

(21) Appl. No.: 19/176,143

(22) Filed: Apr. 10, 2025

Related U.S. Application Data
(60) Provisional application No. 63/632,492, filed on Apr. 10, 2024.

(51) Int. Cl. H05K 7/20; B64G 1/58

(52) U.S. Cl. CPC H05K 7/20936; B64G 1/58

(57) ABSTRACT

This disclosure relates to a local thermal regulation solution for high-power electronics or printed circuit assemblies for use onboard satellites. Thermal regulation is achieved by immersing electronic components in a dielectric phase change material (PCM) within an encapsulating hermetically sealed enclosure. The dielectric PCM can absorb transient thermal spikes during intermittent high-power operations then release this stored energy during low points in the duty cycle. The released thermal energy can be conducted to the vehicle structure via a mounting interface of the enclosure, whereby it is eventually radiated to deep space by the external vehicle surfaces via blackbody radiation. An integrated expansion relief mechanism, which can include pistons, viscoelastic dampers, membranes, and/or bellows, compensates for volumetric changes during PCM phase transitions, ensuring a homogeneous, pressurized mixture optimized for heat absorption. The PCM can also act as a vibration dampener and radiation shield.

### RELATED APPLICATIONS

The subject matter of this application is related to U.S. Provisional Application No. 63632492, filed on Apr. 10, 2024, which is hereby incorporated by reference in its entirety.

### BACKGROUND OF THE INVENTION

High-power spacecraft electronics face significant thermal challenges. Commercial off-the-shelf (COTS) components, when used in space, experience transient thermal spikes during intermittent high-power operations. Thermal management approaches traditionally used for COTS components in non-spacecraft applications are ineffective in the absence of convective cooling in spacecraft implementations. It is known to use a phase change material (PCM) as a separate encapsulated component thermal management in spacecraft, however, conventional solutions, such as hermetically sealed or gas-filled enclosures, suffer from pressure vessel limitations, potential leaks, and limited heat capacity.

### SUMMARY OF THE INVENTION

This disclosure relates to a local thermal regulation solution for high-power electronics or printed circuit assemblies for use onboard satellites. Thermal regulation is achieved by immersing electronic components in a dielectric phase change material (PCM) within an encapsulating hermetically sealed enclosure. The dielectric PCM can absorb transient thermal spikes during intermittent high-power operations then release this stored energy during low points in the duty cycle. The released thermal energy can be conducted to the vehicle structure via a mounting interface of the enclosure, whereby it is eventually radiated to deep space by the external vehicle surfaces via blackbody radiation. An integrated expansion relief mechanism, which can include pistons, viscoelastic dampers, membranes, and/or bellows, compensates for volumetric changes during PCM phase transitions, ensuring a homogeneous, pressurized mixture optimized for heat absorption. The PCM can also act as a vibration dampener and radiation shield.

In one embodiment, a satellite includes a power source; a heat radiating structure; a hermetically sealed enclosure physically and thermally coupled to the heat radiating structure, the enclosure enclosing: a mass of phase change material thermally coupled to the enclosure; and a set of electronic components powered by the power source and immersed in and thermally coupled to the mass of phase change material, the enclosure comprising an expansion relief mechanism configured to maintain pressure in and allow for changes in volume of the mass of phase change material within the enclosure, wherein during operation of the set of electronic components: heat produced by the set of electronic components is absorbed the mass of phase change material through changes in phase; and heat absorbed by the mass of phase change material is absorbed by the heat radiating structure to reverse the changes in phase.

The heat radiating structure can be a satellite structure. The heat radiating structure can include a heat radiating panel. The expansion relief mechanism can include a piston. The expansion relief mechanism can include a bellows. The expansion relief mechanism can include a membrane. The expansion relief mechanism can include a viscoelastic damper.

The phase change material can include short chain additives that mitigate thermal stresses and ensure a homogeneous material composition. The phase change material can be a mixture of paraffin with 10 to 50 percent by volume isododecane. The phase change material can be a mixture of petroleum jelly with 10 to 50 percent by volume isododecane.

As will be appreciated by one skilled in the art, multiple aspects described in this summary can be variously combined in different operable embodiments. All such operable combinations, though they may not be explicitly set forth in the interest of efficiency, are specifically contemplated by this disclosure.

### BRIEF DESCRIPTION OF THE DRAWINGS

FIG. 1 illustrates an overview of a satellite incorporating a PCM-filled enclosure 110 encasing high-power on-board electronic subsystems.

FIGS. 2A-C illustrate a perspective and two cross section functional views of a PCM-filled hermetic enclosure encapsulating a high-power printed circuit assembly or other high-power on-board electronic subsystems.

### DETAILED DESCRIPTION

In the following description, references are made to various embodiments in accordance with which the disclosed subject matter can be practiced. Some embodiments may be described using the expressions one/an/another embodiment or the like, multiple instances of which do not necessarily refer to the same embodiment. Particular features, structures or characteristics associated with such instances can be combined in any suitable manner in various embodiments unless otherwise noted. By way of example, this disclosure may set out a set or list of a number of options or possibilities for an embodiment, and in such case, this disclosure specifically contemplates all clearly feasible combinations and/or permutations of items in the set or list.

This disclosure relates to a local thermal regulation solution for high-power electronics or printed circuit assemblies for use onboard satellites. Thermal regulation is achieved by immersing electronic components in a dielectric phase change material (PCM) within an encapsulating hermetically sealed enclosure. The dielectric PCM can absorb transient thermal spikes during intermittent high-power operations then release this stored energy during low points in the duty cycle. The released thermal energy can be conducted to the vehicle structure via a mounting interface of the enclosure, whereby it is eventually radiated to deep space by the external vehicle surfaces via blackbody radiation. An integrated expansion relief mechanism, which can include pistons, viscoelastic dampers, membranes, and/or bellows, compensates for volumetric changes during PCM phase transitions, ensuring a homogeneous, pressurized mixture optimized for heat absorption. The PCM can also act as a vibration dampener and radiation shield.

The disclosed system enables commercial off-the-shelf (COTS) electronic assemblies to be operated in space, as well as improving the operation of space-grade electronic hardware on satellites, spacecraft, space stations, inter-planetary, and/or lunar vehicles or other vehicles or stations intended to operate in a vacuum or near vacuum environment. The particular PCM can be selected based on its non-conductive properties and an appropriate melting point. The enclosure can be designed to protect the electronic components from the space environment and launch conditions (vacuum, ionizing radiation, vibration, and mechanical shock) while allowing traditional terrestrial thermal management solutions such as heat sinks, heat pipes, and active or passive liquid cooling systems to be used with minimal modifications.

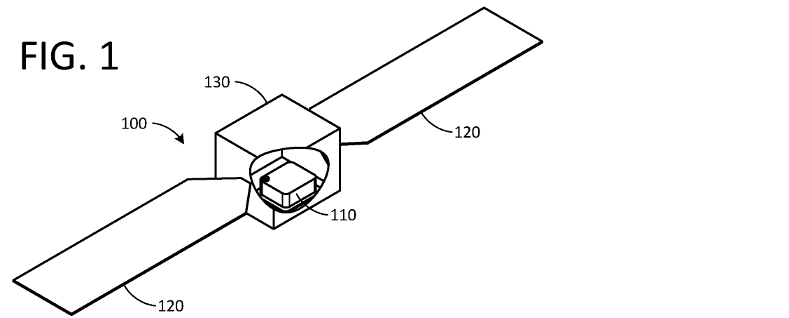

FIG. 1 illustrates an overview of a satellite 100 incorporating a PCM-filled enclosure 110 encasing high-power on-board electronic subsystems. The satellite has a power source, such as solar arrays or deployable solar panels 120, which are used to power on-board electronic systems. The on-board electronic systems can include high-power electronics such as power management systems, electrical converters, amplifiers, RF equipment, propulsion power systems, and/or battery management systems. High-power on-board systems can be located inside the PCM-filled enclosure, whereby the PCM performs a thermal dampening function by absorbing and releasing heat at least in part via phase changes within the PCM. The enclosure can be hard-mounted to the satellite structure 130 with a conductive thermal interface to allow thermal load generated inside the enclosure and/or absorbed by the PCM to be transferred to the outer surfaces of the satellite and radiated to space. In addition or alternatively, a separate heat radiating structure, such as a panel, can be used.

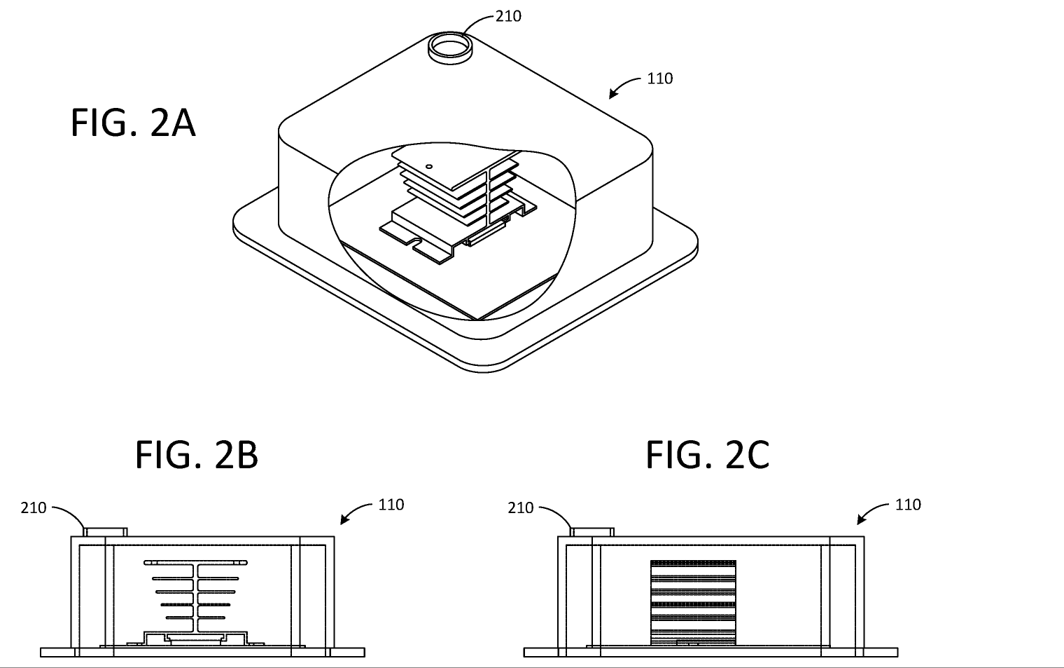

FIGS. 2A-C illustrate a perspective and two cross section functional views of a PCM-filled hermetic enclosure 110 encapsulating a high-power printed circuit assembly or other high-power on-board electronic subsystems. The enclosure 110 can have a clamshell or split design of two halves or sides, with an O-ring, gasket, or other sealing solution forming a hermetic joint between the two halves. The enclosure can include an expansion relief mechanism 210, described further below, to allow for expansion and contraction of the PCM during phase and temperature changes. The enclosure may be filled through the expansion relief mechanism via a process which ensures there are no voids or bubbles in the final assembly. The enclosure can include a hermetic feedthrough, such as a hermetic connector, to provide electrical access to the systems within.

The electronics within the enclosure can be exposed directly to the PCM for thermal regulation. The components can alternatively or additionally be connected to a heat spreader or localized thermal management features such as heat sinks, heat pipes, and active or passive liquid cooling systems that can dissipate heat within the enclosure to the PCM. Such components, which can also be immersed in the PCM within the enclosure, can facilitate the transfer of thermal load from the electronics to the PCM, since the PCM may have a relatively low thermal conductivity.

An integrated expansion relief mechanism can compensate for volumetric changes that can occur as the PCM undergoes phase transitions and temperature changes. This expansion relief mechanism can include one or more pistons, viscoelastic dampers, membranes, or bellows to maintain pressurization during volume changes of the encapsulated media with respect to the enclosure. The maintenance of pressure on the PCM within the enclosure prevents the formation of vacuum bubbles that can cause slosh during launch loads and inconsistent cooling during operation. By ensuring that the PCM remains uniformly pressurized and free of voids, the system can deliver repeatable and consistent thermal performance.

The expansion relief mechanism can be configured for resilience to a launch vibration environment. The mechanism should maintain sufficient stiffness during launch to possess a high first vibrational mode such that it does not couple with the spacecraft primary mode. Meanwhile, the mechanism should be compliant enough to allow for pressure relief. To meet both of these requirements, it may be necessary to employ a hold-down release mechanism to restrain the expansion relief mechanism during launch, then release the hold-down release mechanism during spacecraft commissioning on orbit. Alternatively non-newtonian and viscoelastic effects can be used to ensure stiffness under high frequency vibration, but compliance during low frequency pressurization cycles, for example a constrained aperture mesh.

The PCM can be engineered to remain in a liquid-like state over an extended temperature range by incorporating short chain or other additives that mitigate thermal stresses and ensure a homogeneous material composition. The formation of a heterogeneous mixture could induce complex thermomechanical effects such as pressure buildup in constrained volumes within the enclosure. One example composition for a PCM is a mixture of paraffin/petroleum jelly with 10 - 50 volume percent isododecane. Alternatively, the PCM can be encapsulated in hollow beads, such as PMMA-encapsulated paraffin beads, and suspended in mineral oil, such that the mixture remains in a liquid state when the PCM is solid within the suspended beads.

While certain thermal management components may have been originally designed for operation in ambient air on earth, the PCM or a non-conductive liquid can provide a sufficiently similar thermal environment for them to effectively operate. Even fans designed for use in air can be immersed and operated in non-conductive liquids, such as mineral oil, in an active liquid cooling system as demonstrated in 2007 by www.pugetsystems.com/mineral-oil-pc. In one embodiment, the electronics can be immersed in a (preferably non-conductive) liquid that can be circulated to in turn exchange heat with a PCM. The liquid can exchange heat with the PCM by way of a heat exchanger, such as a circulation conduit embedded within a volume of PCM.

The approaches described above allow for terrestrial hardware to be used on spacecraft with little modification of their thermal management, as the above techniques can be used in conjunction with existing heat removal methods such as heatsinks, heat pipes, and active or passive liquid cooling systems. Space qualified electronics are typically substantially more expensive and underperforming compared to their terrestrial counterparts, therefore the disclosed solution brings significant cost and performance benefits to builders and operators of space hardware.

Although the subject matter has been described in terms of certain embodiments, other embodiments that may or may not provide various features and aspects set forth herein shall be understood to be contemplated by this disclosure. The specific embodiments set forth herein are disclosed as examples only, and the scope of the patented subject matter is defined by the claims that follow.

1. A satellite comprising:
a power source;
a heat radiating structure;
a hermetically sealed enclosure physically and thermally coupled to the heat radiating structure, the enclosure enclosing:
a mass of phase change material thermally coupled to the enclosure; and
a set of electronic components powered by the power source and immersed in and thermally coupled to the mass of phase change material,
the enclosure comprising an expansion relief mechanism configured to maintain pressure in and allow for changes in volume of the mass of phase change material within the enclosure,
wherein during operation of the set of electronic components:
heat produced by the set of electronic components is absorbed the mass of phase change material through changes in phase; and
heat absorbed by the mass of phase change material is absorbed by the heat radiating structure to reverse the changes in phase.

2. The satellite of claim 1, wherein the heat radiating structure is a satellite structure.

3. The satellite of claim 1, wherein the heat radiating structure comprises a heat radiating panel.

4. The satellite of claim 1, wherein the expansion relief mechanism comprises a piston.

5. The satellite of claim 1, wherein the expansion relief mechanism comprises a bellows.

6. The satellite of claim 1, wherein the expansion relief mechanism comprises a membrane.

7. The satellite of claim 1, wherein the expansion relief mechanism comprises a viscoelastic damper.

8. The satellite of claim 1, wherein the phase change material comprises short chain additives that mitigate thermal stresses and ensure a homogeneous material composition.

9. The satellite of claim 1, wherein the phase change material is a mixture of paraffin with 10 to 50 percent by volume isododecane.

10. The satellite of claim 1, wherein the phase change material is a mixture of petroleum jelly with 10 to 50 percent by volume isododecane.
